(19) United States
(12) Patent Application Publication
(10) Pub. No.: US 2004/0082198 A1
(43) Pub. Date: Apr. 29, 2004

(54) Method of manufacturing semiconductor device

(76) Inventors: Manabu Nakamura, Aizuwakamatsu (JP); Hiroyuki Nansei, Aizuwakamatsu (JP); Kentaro Sera, Aizuwakamatsu (JP); Masahiko Higashi, Aizuwakamatsu (JP); Yukihiro Utsuno, Alizuwakatsu (JP); Hideo Takagi, Aizuwakamatsu (JP); Tatsuya Kajita, Aizuwakamatsu (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(21) Appl. No.: 10/659,748

(22) Filed: Sep. 11, 2003

(30) Foreign Application Priority Data
Sep. 19, 2002 (JP) 2002-273625

(51) Int. Cl. H01L 21/31

(52) U.S. Cl. 438/787

(57) ABSTRACT

A chemical oxide film formed on a semiconductor substrate is formed by wet cleaning using a strongly acidic solution so that the adhesion of impurities to the chemical oxide film can be reduced between a wet cleaning process and an insulation film forming process. This makes it possible to prevent insulation degradation of a gate insulation film when the gate insulation film embracing the chemical oxide film is formed in the insulation film forming process in which low-temperature processing is conducted.

### CROSS-REFERENCE TO RELATED APPLICATIONS

This application is based upon and claims the benefit of priority from the prior Japanese Patent Application No. 2002-273625, filed on Sep. 19, 2002, the entire contents of which are incorporated herein by reference.

### BACKGROUND OF THE INVENTION

1. Field of the Invention

The present invention relates to a method of manufacturing a semiconductor device, and more particularly, to that suitable for use in forming a gate insulation film.

2. Description of the Related Art

In manufacturing a semiconductor device, a cleaning process of a semiconductor substrate is prepared between a certain manufacturing process and a subsequent manufacturing process since adhesion of very small particles and a very small amount of impurities obstructs the realization of a high-performance, high-reliability semiconductor device. For this cleaning process, various cleaning methods are available, among which wet cleaning using a solution containing hydrochloric acid or the like is in the mainstream at present.

However, when the insulation film is to be formed on the semiconductor substrate, the amount of impurities such as organic matter adhering to the the elapse of the standing time after the semiconductor substrate undergoes the aforesaid wet cleaning. Conventionally, since a chemical oxide film formed at the time of the wet cleaning comprises a solution containing hydrochloric acid to which the impurities such as organic matter easily adhere, the impurities give rise to an adverse effect with the elapse of the standing time.

More specifically, when a gate oxide film or a tunnel oxide film embracing the aforesaid chemical oxide film is formed, there exists a problem that the adhesion of the impurities such as organic matter causes rapid insulation degradation of the oxide film with the elapse of the standing time between the wet cleaning to the formation of the oxide film so that reliability cannot be ensured.

### SUMMARY OF THE INVENTION

The present invention is made in view of the above-described problem, and its object is to realize a method of manufacturing a reliable semiconductor device in which the amount of impurities are reduced in forming an insulation film (second insulation film) such as a gate insulation film, a tunnel insulation film, or the like.

After assiduous studies, the inventor of the present invention has come up with the following form of the invention.

A method of manufacturing a semiconductor device according to the present invention is characterized in that it comprises the steps of: forming a first insulation film by oxidizing a surface of a semiconductor substrate using a strongly acidic solution after cleaning the surface of the semiconductor substrate; and forming a second insulation film embracing the first insulation film by low-temperature processing.

### BRIEF DESCRIPTION OF THE DRAWINGS

FIG. 1A and FIG. 1B are schematic views showing the basic structure of a method of manufacturing a semiconductor device in the present invention;

FIG. 2A to FIG. 2D are schematic cross sectional views showing a method of manufacturing a SONOS-type semiconductor memory device in an embodiment of the present invention in the order of processes;

FIG. 3A to FIG. 3D are schematic cross sectional views, subsequent to FIG. 2A to FIG. 2D, showing the method of manufacturing the SONOS-type semiconductor memory device in the embodiment of the present invention in the order of processes;

FIG. 4A to FIG. 4D are schematic cross sectional views, subsequent to FIG. 3A to FIG. 3D, showing the method of manufacturing the SONOS-type semiconductor memory device in the embodiment of the present invention in the order of processes;

FIG. 5A to FIG. 5C are schematic cross sectional views, subsequent to FIG. 4A to FIG. 4D, showing the method of manufacturing the SONOS-type semiconductor memory device in the embodiment of the present invention in the order of processes;

FIG. 6A and FIG. 6B are schematic views of a memory region of the SONOS-type semiconductor memory device in the embodiment;

FIG. 7 is a schematic block diagram of a plasma processor for conducting plasma oxidizing and plasma nitriding; and

FIG. 8A and FIG. 8B are characteristic charts of withstand voltage of a gate insulation film.

### DETAILED DESCRIPTION OF THE PREFERRED EMBODIMENTS

### Basic Structure of Method of Manufacturing Semiconductor Device in Present Invention

The basic structure of a method of manufacturing a semiconductor device in the present invention will be hereinafter explained.

Conventionally, a thin chemical oxide film is formed on a semiconductor substrate by wet cleaning using a solution containing hydrochrolic acid. This chemical oxide film which is formed using the solution containing hydrochrolic acid, however, has a large surface area due to irregularity caused on the surface thereof so that impurities such as organic matter easily adhere thereto. Because of this, when an insulation film such as a gate oxide film or a tunnel oxide film is formed so as to embrace this chemical oxide film by low-temperature processing (650° C. or lower) instead of thermal oxidation, for example, by direct plasma oxidation or direct plasma nitridation, the impurities such as organic matter are not removed due to the low forming temperature thereof. Consequently, the impurities give rise to a significant adverse effect.

Under the above circumstances, the inventor of the present invention has worked out a method of manufacturing a semiconductor device with the intention of making a chemical oxide film formed at the time of the wet cleaning a uniform and dense film so as not to allow impurities such as organic matter to easily adhere thereto.

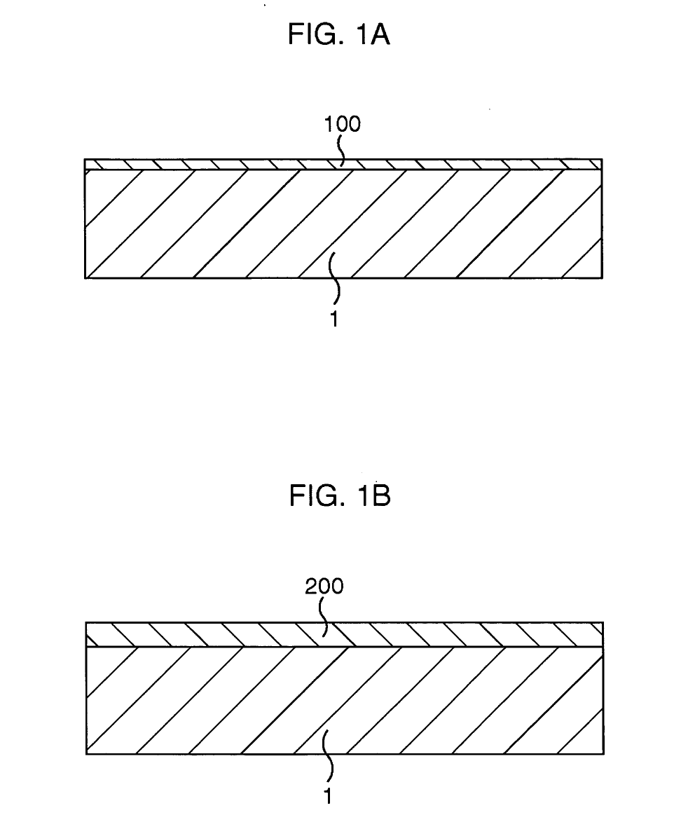

FIG. 1A and FIG. 1B are schematic views showing the basic structure of a method of manufacturing a semiconductor device in the present invention.

As shown in FIG. 1A, a chemical insulation film (first insulation film) 100 is formed on a semiconductor substrate 1 by wet cleaning using a solution having a stronger acidity than a solution containing hydrochrolic acid, for example, a solution containing nitric acid or a solution containing ozone. Here, since the chemical insulation film 100 which is formed using the strongly acidic solution has a strong acidity, the resultant chemical insulation film 100 can be made more uniform and denser than that formed using a solution containing hydrochrolic acid. Therefore, it is possible to reduce the surface area thereof and not to allow the impurities such as organic matter to easily adhere thereto.

Subsequently, as shown in FIG. 1B, a gate insulation film (second insulation film) 200 embracing the chemical oxide film 100 is formed by low-temperature processing using plasma or the like. At this time, since the resultant gate insulation film 200 is formed so as to embrace the chemical oxide film 100 not allowing the impurities such as organic matter to easily adhere thereto, it can be made to have a smaller amount of impurities than that embracing a chemical oxide film formed by using the solution containing hydrochrolic acid.

As described above, the chemical insulation film 100 formed on the semiconductor substrate 1 is formed using the strongly acidic solution for the wet cleaning, thereby enabling the reduction in the amount of the impurities adhering to the chemical insulation film 100 between a wet cleaning process and an insulation film forming process. This can reduce the amount of the impurities such as organic matter at the time of forming the gate insulation film 200 embracing the chemical insulation film 100 in the insulation film forming process in which the low-temperature processing is conducted. Consequently, insulation degradation of the gate insulation film 200 can be prevented.

### Concrete Embodiment to which Present Invention is Applied

Next, an embodiment based on the basic structure of the method of manufacturing the semiconductor device in the present invention will be explained with reference to the attached drawings. In this embodiment, a semiconductor memory device having an embedded-bit-line-type SONOS structure will be disclosed as an example of the semiconductor device. This semiconductor memory device is so structured that SONOS transistors in a memory cell region (core region) are of a planer type and CMOS transistors are formed in a peripheral circuit region.

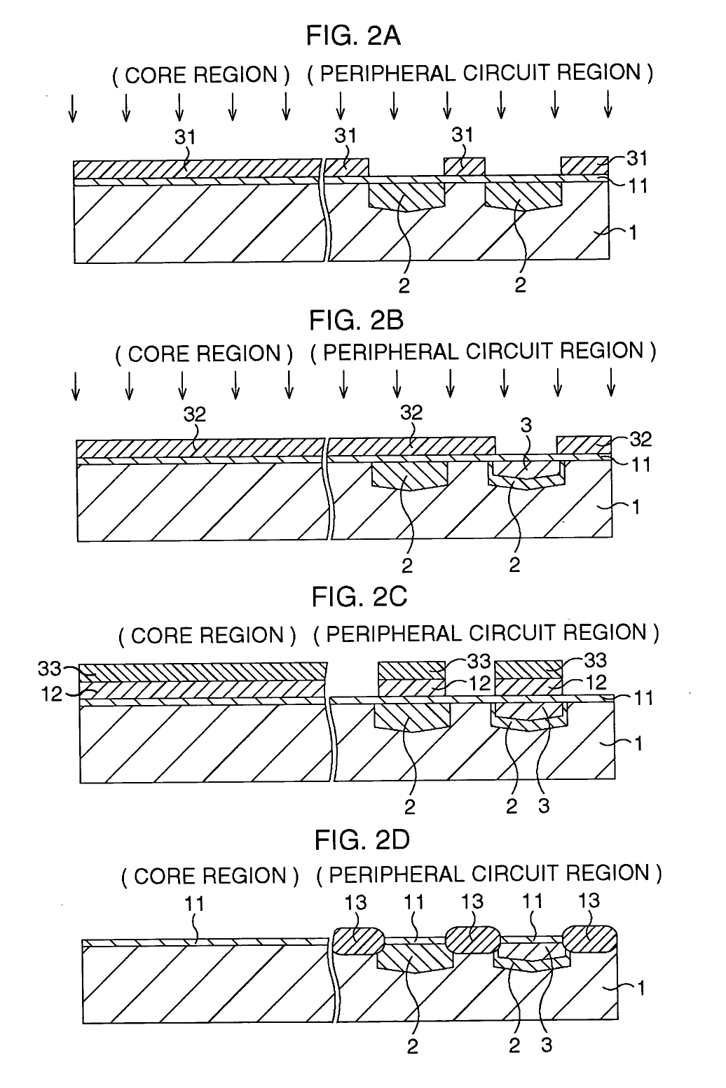

FIG. 2A to FIG. 5C are schematic cross sectional views showing a method of manufacturing a semiconductor memory device including embedded-bit-line-type SONOS transistors in this embodiment in the order of processes. Here, a view on the left side in each of the drawings shows a cross sectional view of the core region taken along the parallel line to a gate electrode (word line) and a view on the right side shows a cross sectional view of a peripheral circuit region.

First, as shown in FIG. 2A, a silicon oxide film (SiO₂ film) 11 is formed to have a film thickness of about 20 nm on the semiconductor substrate 1 comprising P-type silicon (Si) by thermal oxidation. Thereafter, a resist pattern 31 having openings above transistor forming regions of the peripheral circuit region is formed by photolithography, and phosphorus (P) is ion-implanted onto the entire surface. Thereafter, impurities are thermally diffused by annealing to form N-wells 2. Thereafter, the resist pattern 31 is removed by ashing or the like using O₂ plasma.

Subsequently, as shown in FIG. 2B, a resist pattern 32 having openings above NMOS transistor forming regions of the peripheral circuit region is formed by photolithography, and boron (B) is ion-implanted over the entire surface. Thereafter, the impurities are thermally diffused by annealing to form P-wells 3 so as to form a triple-well structure in the NMOS transistor forming regions. Thereafter, the resist pattern 32 is removed by ashing or the like using O₂ plasma.

Subsequently, as shown in FIG. 2C, a silicon nitride film 12 is deposited on the silicon oxide film 11 to have a film thickness of about 100 nm by a CVD method. Then, a resist pattern 33 having openings above element isolation regions of the peripheral circuit region is formed by photolithography, and the silicon nitride film 12 in the element isolation regions are made open by dry etching. Thereafter, the resist pattern 33 is removed by ashing or the like using O₂ plasma.

Subsequently, as shown in FIG. 2D, a thick silicon oxide film 13 for element isolation is formed by a so-called LOCOS method only on portions not covered with the silicon nitride film 12 to demarcate element active regions. Thereafter, the silicon nitride film 12 is removed by dry etching.

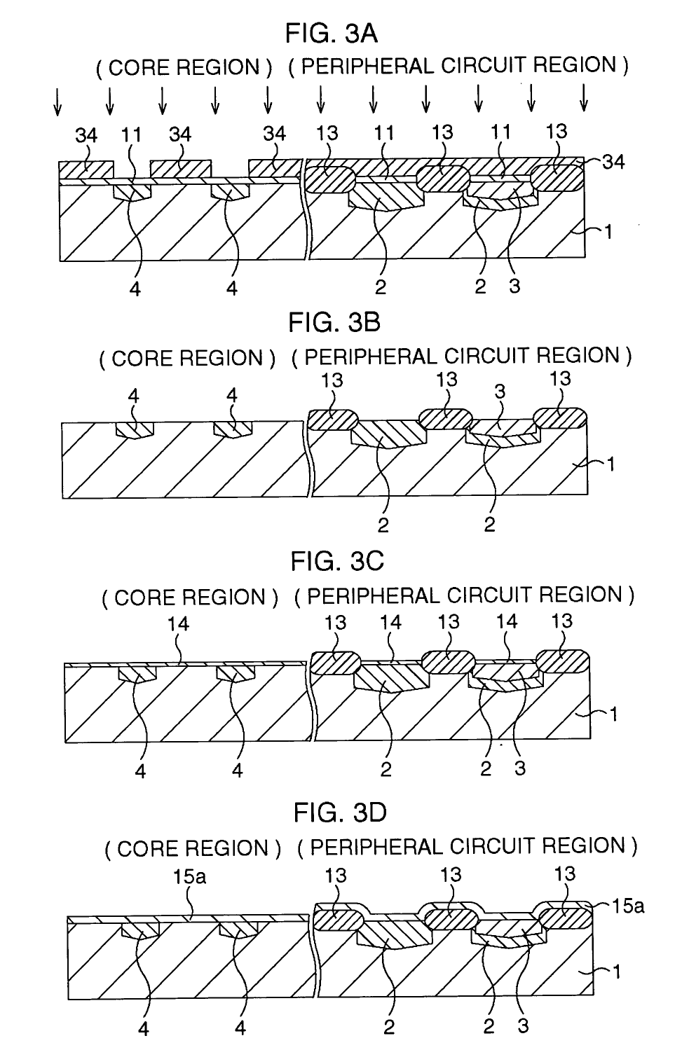

Subsequently, as shown in FIG. 3A, a resist pattern 34 in a bit-line shape is formed by photolithography, and using this resist pattern 34 as a mask, arsenic (As) is ion-implanted onto the entire surface. Thereafter, the impurities are thermally diffused by annealing. Through these processes, bit-line diffusion layers 4 also serving as sources/drains are formed in the core region. Thereafter, the resist pattern 34 is removed by ashing or the like using O₂ plasma.

Subsequently, as shown in FIG. 3B, the silicon oxide film 11 is removed by wet etching using hydrofluoric acid (HF) to expose the surface of the semiconductor substrate 1 in the core region and each of the element active regions in the peripheral circuit region.

Subsequently, as shown in FIG. 3C, a chemical oxide film (first insulation film) 14 is formed to have a film thickness of, for example, about 1.0 nm to about 1.5 nm by wet cleaning using a strongly acidic solution containing nitric acid at 70° C. or higher. Here, the chemical oxide film 14 is a uniform and dense film since it is formed using the strongly acidic solution.

It should be noted that the strongly acidic solution is defined in the present invention as a higher oxidative solution than a solution containing hydrochrolic acid, and is not limited to the solution containing nitric acid shown in this embodiment. Any solution is applicable as long as the essential property described above is satisfied. For example, a solution containing ozone or the like is also applicable.

Subsequently, an ONO film as a multilayered insulation film is formed. Here, a plasma oxidizing method and a plasma nitriding method through microwave excitation which are used for forming this ONO film will be explained in detail.

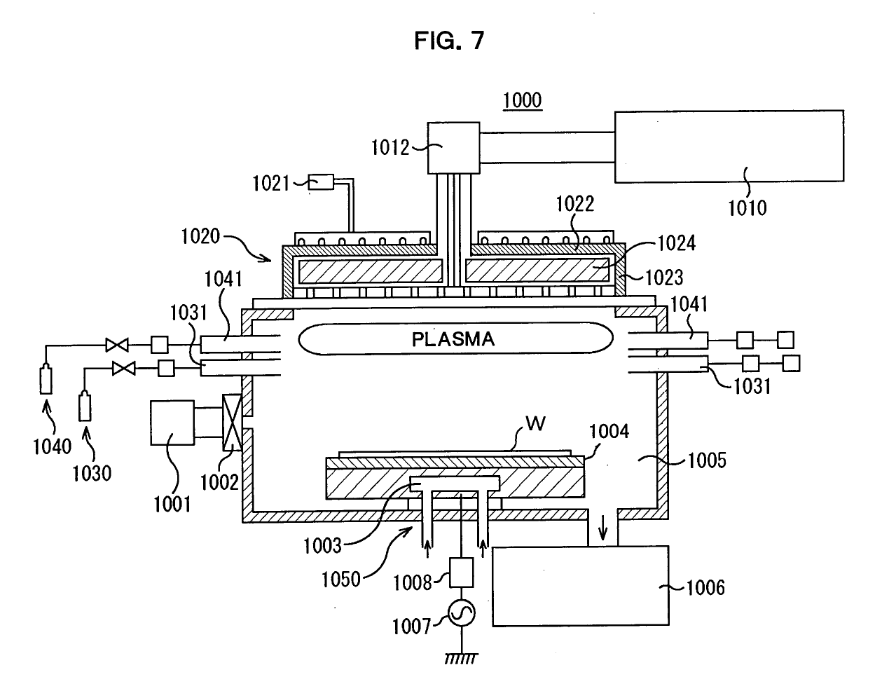

Specifically, a plasma processor, as shown in FIG. 7, provided with a radial line slot antenna is used for plasma oxidizing and plasma nitriding.

This plasma processor 1000 includes a gate valve 1002 communicating with a cluster tool 1001, a process chamber 1005 capable of accommodating a susceptor 1004 on which an object W to be processed (the semiconductor substrate 1 in this embodiment) is to be mounted and which is provided with a cooling jacket 1003 for cooling the object W to be processed at the time of plasma processing, a high-vacuum pump 1006 connected to the process chamber 1005, a microwave supply source 1010, an antenna member 1020, a bias high-frequency power source 1007 and a matching box 1008 constituting an ion plating apparatus together with this antenna member 1020, gas supply systems 1030, 1040 having gas supply rings 1031, 1041, and a temperature control section 1050 for controlling the temperature of the object W to be processed.

The microwave supply source 1010 comprises, for example, magnetron and is generally capable of generating a microwave (for example, 5 kW) of 2.45 GHz. The transmission mode of the microwave is thereafter converted to a TM, TE, TEM mode or the like by a mode converter 1012.

The antenna member 1020 has a temperature adjusting plate 1022 and an accommodating member 1023. The temperature adjusting plate 1022 is connected to a temperature control unit 1021, and the accommodating member 1023 accommodates a wavelength shortening material 1024 and a slot electrode (not shown) being in contact with the wavelength shortening material 1024. This slot electrode is called a radial line slot antenna (RLSA) or an ultra-high efficiency flat antenna. In this embodiment, however, a different type of antenna, for example, a single-layer waveguide flat antenna, a dielectric substrate parallel plane slot array, or the like may be applied.

In forming the ONO film of this embodiment using the plasma processor as structured above, a tunnel oxide film (silicon oxide film) 15a embracing the chemical oxide film 14 is first formed to have a film thickness of about 7 nm by a plasma oxidizing method at a low temperature (650° C. or lower) as shown in FIG. 3D.

More specifically, an oxide radical (O* radical or OH* radical) is generated by irradiating a source gas containing oxide atoms with a microwave of 2 kW in an atmosphere of this source gas under the temperature condition of about 450° C. to conduct oxidizing, thereby forming the tunnel oxide film 15a.

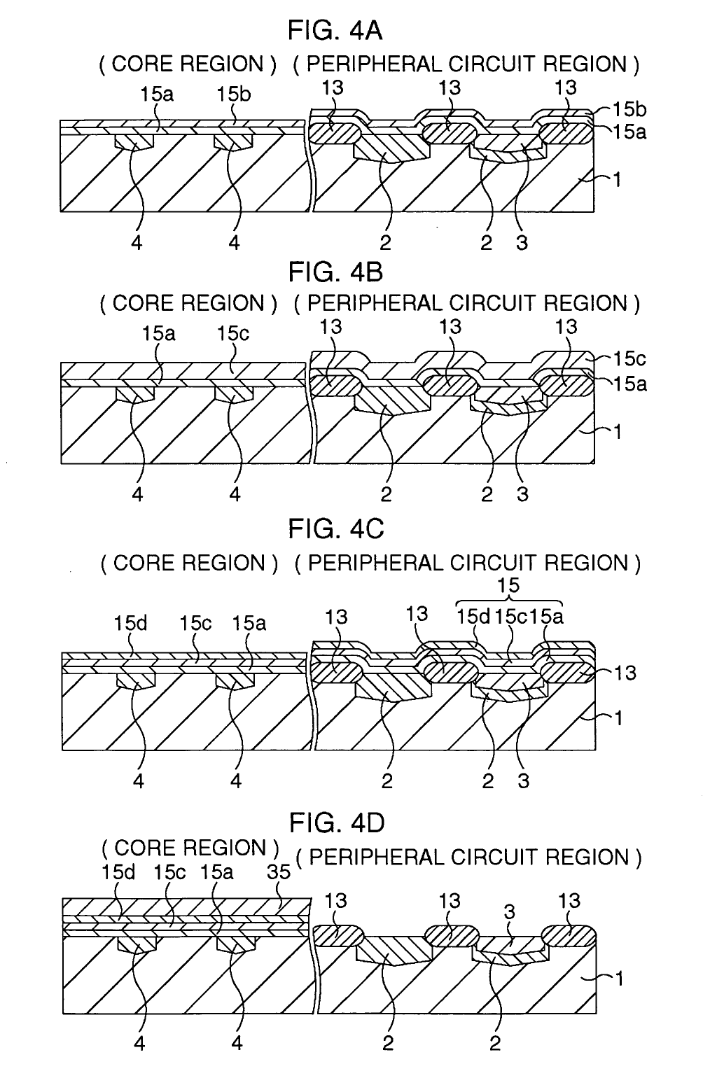

Subsequently, as shown in FIG. 4A, an amorphous silicon film 15b is deposited to have a film thickness of about 10 nm on the tunnel oxide film 15a by a thermal CVD method under the temperature condition of 530° C., using SiH₄ as a source gas. Here, a polycrystalline silicon film may be formed instead of the amorphous silicon film.

Subsequently, as shown in FIG. 4B, the amorphous silicon film 15b is completely nitrided by a plasma nitriding method to form a silicon nitride film 15c on the tunnel oxide film 15a.

Specifically, a source gas containing nitride atoms, for example, an NH₃ gas, is irradiated with a microwave of 2 kW in an atmosphere of this source gas, under the temperature condition of about 450° C. to generate a nitride radical (N* radical or NH* radical), thereby conducting nitriding. The amorphous silicon film 15b having a film thickness of about 10 nm is completely nitrided to be replaced by the silicon nitride film 15c having a film thickness of about 15 nm.

Subsequently, as shown in FIG. 4C, the surface of the silicon nitride film 15c is oxidized by a plasma oxidizing method to form a silicon oxide film 15d.

Specifically, a source gas containing oxide atoms is irradiated with a microwave of 2 kW in an atmosphere of this source gas under the temperature condition of about 450° C. to generate an oxide radical (O* radical or OH* radical), thereby conducting oxidizing to form the silicon oxide film 15d. Through these processes, the ONO film 15 constituted of three films 15a, 15c, 15d is formed.

Subsequently, as shown in FIG. 4D, a resist pattern 35 having an opening above the peripheral circuit region is formed by photolithography, and the ONO film 15 in the peripheral circuit region is removed by dry etching. Thereafter, the resist pattern 35 is removed by ashing or the like using O₂ plasma.

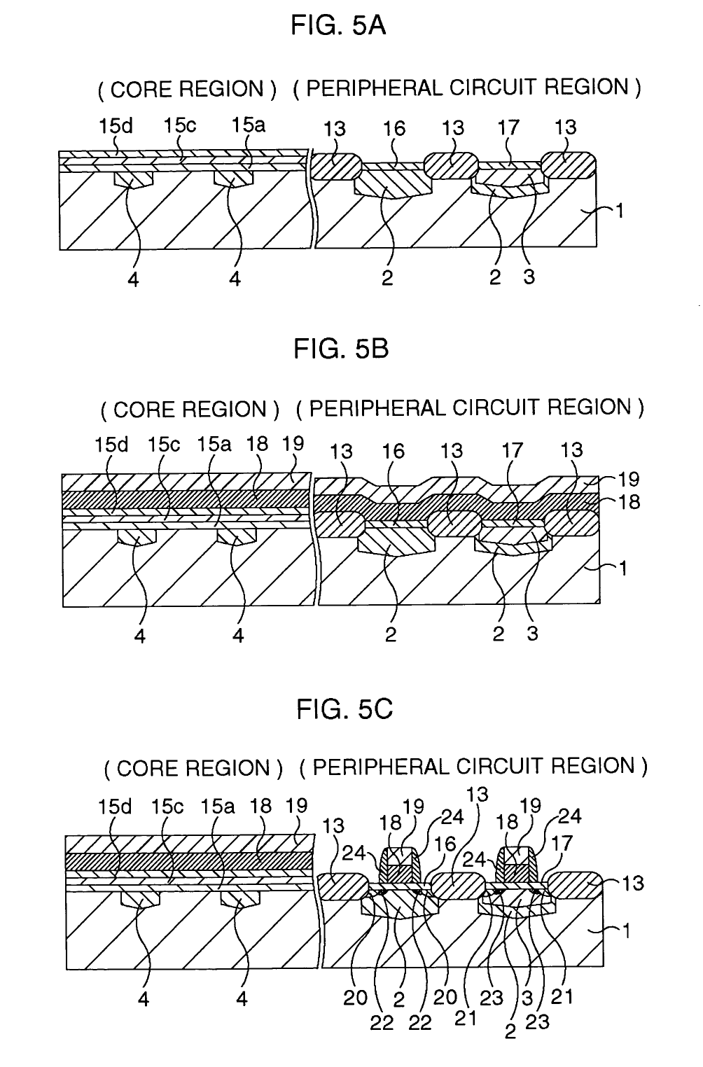

Subsequently, as shown in FIG. 5A, the surface of the semiconductor substrate 1 undergoes high-temperature heating under the temperature condition of about 1000° C., and a silicon oxide film (SiO₂ film) is formed to have a film thickness of about 8 nm. Thereafter, a not-shown resist pattern having openings above PMOS transistor forming regions of the peripheral circuit region is formed by photolithography, and the silicon oxide film in the PMOS transistor forming regions is removed by wet etching using hydrofluoric acid (HF). Further, this not-shown resist pattern is removed by ashing or the like using O₂ plasma. Thereafter, the surface of the semiconductor substrate 1 undergoes high-temperature heating again under the temperature condition of 1000° C. to form a silicon oxide film to have a film thickness of about 10 nm. Through these processes, two different kinds of gate insulation films, namely, a gate insulation film 16 having a film thickness of about 10 nm in the PMOS transistor forming regions and a gate insulation film 17 having a film thickness of about 13 nm in the NMOS transistor forming regions are formed.

Subsequently, as shown in FIG. 5B, a polycrystalline silicon film 18 is deposited in the core region and the peripheral circuit region to have a film thickness of about 100 nm by a CVD method. Further, a tungsten silicide 19 is deposited on the polycrystalline silicon film 18 to have a film thickness of about 150 nm by a CVD method.

Subsequently, as shown in FIG. 5C, the tungsten silicide 19 and the polycrystalline silicon film 18 are patterned by photolithography followed by dry etching to form gate electrodes constituted of the tungsten silicide 19 and the polycrystalline silicon film 18 in the core region and the PMOS transistor forming regions and the NMOS transistor forming regions of the peripheral circuit region respectively. At this time, this gate electrode in the core region is formed to cross a bit line diffusion layer 4 substantially perpendicularly.

Further, sources/drains 20, 21 having an LDD structure is formed only in the peripheral circuit region.

Specifically, p-type impurities are ion-implanted onto the surface of the semiconductor substrate 1 on both sides of the gate electrodes in the PMOS transistor forming regions to form extension regions 22. Meanwhile, in the NMOS transistor forming regions, n-type impurities are ion-implanted onto the surface of the semiconductor substrate 1 on both sides of the gate electrodes to form extension regions 23.

Next, after a silicon oxide film is deposited over the entire surface by a CVD method, the entire surface of this silicon oxide film is antisotropically etched (etchback) so as to leave only the silicon oxide film on both sides of each gate electrode, thereby forming sidewalls 24.

Then, in the PMOS transistor forming regions, p-type impurities are ion-implanted onto the surface of the semiconductor substrate 1 on both sides of the gate electrodes and the sidewalls to form the deep sources/drains 20 which partly overlap the extension regions 22. Meanwhile, in the NMOS transistor forming regions, n-type impurities are ion-implanted onto the surface of the semiconductor substrate 1 on both sides of the gate electrodes and the sidewalls 24 to form the deep sources/drains 21 which partly overlap the extension regions 23.

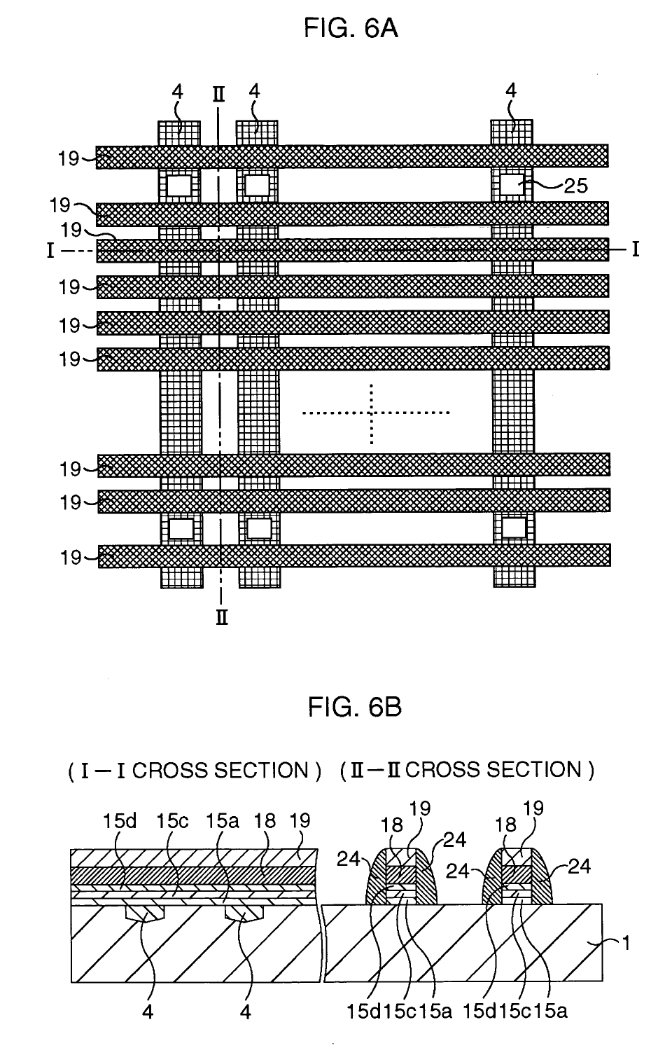

Thereafter, a several-layered interlayer insulation film covering the entire surface, contact holes, via holes, various kinds of wiring layers, and so on are formed, and a protective insulation film (none of them are shown) is formed on the top layer so that, on the semiconductor substrate 1, a SONOS memory cell array is formed in the core region and CMOS transistors are formed in the peripheral circuit region. At this time, the bit line diffusion layers 4 in the core region is backed with wirings. Here, a schematic view of the core region is shown in FIG. 6A, and a cross sectional view taken along the I-I line and a cross sectional view taken along the II-II line in FIG. 6A are shown in FIG. 6B. As shown in FIG. 6A, in the bit line diffusion layers 4, contact hole forming portions 25 for backing with the wirings are formed at predetermined places, each of the contact hole forming portions 25 being formed at one word line 19 out of 16 word lines 19.

Through the above-described processes, the semiconductor memory device of this embodiment is completed.

In this embodiment, the LOCOS method is used as an element isolation method, but an STI (Shallow Trench Isolation) method may be used. As a method of plasma oxidation, a method of introducing a source gas into an ordinary single-wafer-processing-type plasma chamber to generate an oxygen radical (O*) may be used. As the gate electrodes, the tungsten silicide is formed on the polycrystalline silicon film, but siliciding may be conducted using cobalt or the like. The core region is constituted of the planar type transistors, but a so-called oxidized bit-line type may be used. The semiconductor substrate may be an N-type and the crystal face direction may be (100) or (111). Further, the bit lines may be backed at one word line out of 8 word lines, out of 32 word lines, or out of 20 word lines. Further, the structure of the memory cell array in the core region in this embodiment is a virtual ground type, but it may be a NOR type, a NAND type, or may have other structures.

### Characteristic Verification Result of Semiconductor Device

In the semiconductor device shown in FIG. 1A and FIG. 1B, comparison verification of electric characteristics is made between the case when the chemical oxide film (first insulation film) 100 is formed using a solution containing hydrochrolic acid as in the conventional method and in the case when it is formed using a solution containing nitric acid as shown in this embodiment.

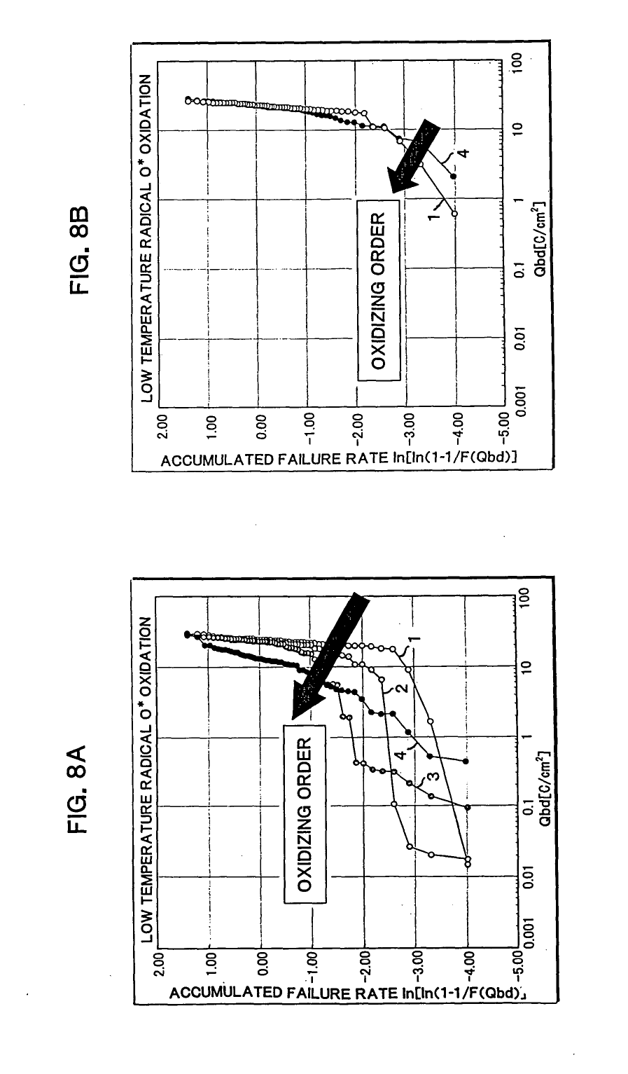

FIG. 8A and FIG. 8B are characteristic charts of withstand voltage of the gate insulation film 200. FIG. 8A is a characteristic chart of semiconductor devices in which the chemical oxide film 100 is formed using a solution containing hydrochrolic acid, and FIG. 8B is a characteristic chart of semiconductor devices in which the chemical oxide film 100 is formed using a solution containing nitric acid. Here, the concentration of each of the solutions is about 10 wt % to about 60 wt %.

In these characteristic charts, the vertical axis shows an accumulated failure rate and the horizontal axis shows the amount of electricity leading to dielectric breakdown of the gate insulation film 200. The characteristics connected by one solid line are for one semiconductor device. ‘1’ is a measurement sample in which the gate insulation film 200 is formed by low-temperature processing (O* radical) immediately after the chemical oxide film 100 is formed. ‘2’ is a measurement sample in which the gate insulation film 200 is formed by low-temperature processing after the semiconductor substrate is left as it is for one hour after the chemical oxide film 100 is formed. ‘3’ is a measurement sample in which the gate insulation film 200 is formed after the semiconductor substrate is similarly left as it is for two hours. ‘4’ is a measurement sample in which the gate insulation film 200 is formed after the semiconductor substrate is left as it is for three hours.

It is seen that, the semiconductor devices shown in FIG. 8A, in which the chemical oxide film 100 is formed using the solution containing hydrochrolic acid exhibit a great decrease in withstand voltage as the standing time before the formation of the gate insulation film 200 becomes longer. The reason can be imagined as follows. The surface area of the chemical oxide film 100 formed using the solution containing hydrochrolic acid is large due to the irregularity caused on the surface thereof to thereby allowing impurities such as organic matter to easily adhere thereto, so that the amount of the impurities adhering thereto also increases with the elapse of the standing time, and the withstand voltage is greatly lowered due to the impurities.

On the other hand, the semiconductor devices shown in FIG. 8B, in which the chemical oxide film 100 is formed using the solution containing nitric acid exhibit no decrease in withstand voltage even when the standing time before the formation of the gate insulation film 200 becomes longer. The reason can be imagined as follows. Since the chemical oxide film 100 which is formed using the solution containing nitric acid is a uniform and dense film, impurities such as organic matter do not easily adhere thereto and the amount of impurities adhering thereto does not change much even when the standing time becomes longer so that no decrease in withstand voltage is caused either.

The verification results shown in FIG. 8A and FIG. 8B have proved that insulation degradation of an insulation film can be prevented to a larger extent when the chemical oxide film 100 is formed using the solution containing nitric acid which is a strongly acidic solution than when it is formed using the solution containing hydrochrolic acid.

When the second insulation film is formed by the low-temperature processing, the second insulation film is formed so as to embrace the first insulation film which is formed using the strongly acidic solution, thereby enabling the second insulation film to have a small amount of impurities such as organic matter. This makes it possible to realize a method of manufacturing a semiconductor device in which the insulation degradation of the gate insulation film is prevented while reducing stresses to the semiconductor substrate.

The present embodiments are to be considered in all respects as illustrative and no restrictive, and all changes which come within the meaning and range of equivalency of the claims are therefore intended to be embraced therein. The invention may be embodied in other specific forms without departing from the sprit or essential characteristics thereof.

What is claimed is:

1. A method of manufacturing a semiconductor device, comprising the steps of:
forming a first insulation film by oxidizing a surface of a semiconductor substrate using a strongly acidic solution after cleaning the surface of said semiconductor substrate; and
forming a second insulation film embracing said first insulation film by low-temperature processing.

2. The method of manufacturing the semiconductor device according to claim 1,
wherein said second insulation film is formed in an atmosphere containing a radical.

3. The manufacturing method of the semiconductor device according to claim 1,
wherein said second insulation film is formed by plasma oxidation in an atmosphere containing an oxide radical.

4. The method of manufacturing the semiconductor device according to claim 1,
wherein said second insulation film is formed by plasma nitridation in an atmosphere containing a nitride radical.

5. The method of manufacturing the semiconductor device according to claim 1,
wherein said second insulation film is formed as an ONO film.

6. The method of manufacturing the semiconductor device according to claim 1,
wherein said strongly acidic solution is a solution containing nitric acid.

7. The method of manufacturing the semiconductor device according to claim 6,
wherein said solution containing the nitride acid is 70° C. or higher in temperature.

8. The method of manufacturing the semiconductor device according to claim 1,
wherein said strongly acidic solution is a solution containing ozone.

9. The method of manufacturing the semiconductor device according to claim 1,
wherein said low-temperature processing is conducted at a temperature of 650° C. or lower.

10. The method of manufacturing the semiconductor device according to claim 1,
wherein said first insulation film has a film thickness of 1 nm or more.

11. The method of manufacturing the semiconductor device according to claim 1,
wherein said second insulation film is a gate insulation film or a tunnel insulation film.

12. The method of manufacturing the semiconductor device according to claim 2,
wherein said strongly acidic solution is a solution containing nitric acid.

13. The method of manufacturing the semiconductor device according to claim 3,
wherein said strongly acidic solution is a solution containing nitric acid.

14. The method of manufacturing the semiconductor device according to claim 2,
wherein said strongly acidic solution is a solution containing ozone.

15. The method of manufacturing the semiconductor device according to claim 3,
wherein said strongly acidic solution is a solution containing ozone.

16. The method of manufacturing the semiconductor device according to claim 2,
wherein said low-temperature processing is conducted at a temperature of 650° C. or lower.

17. The method of manufacturing the semiconductor device according to claim 2,
wherein said second insulation film is a gate insulation film or a tunnel insulation film.

18. The method of manufacturing the semiconductor device according to claim 3,
wherein said second insulation film is a gate insulation film or a tunnel insulation film.
